(19) United States
(12) Patent Application Publication
(10) Pub. No.: US 2026/0293023 A1
(43) Pub. Date: Sep. 24, 2026

(54) CONNECTOR DISASSEMBLY MODULE AND SERVER HAVING THE SAME

(71) Applicant: Wistron Corporation, New Taipei City (TW)

(72) Inventors: YONG QING ZHONG, New Taipei City (TW); YISHENG CHEN, New Taipei City (TW)

(21) Appl. No.: 19/234,551

(22) Filed: Jun. 11, 2025

(30) Foreign Application Priority Data
Mar. 21, 2025 (CN) 202510347572.5

(51) Int. Cl. H05K 7/14

(52) U.S. Cl. CPC H05K 7/1411; H05K 7/1487

(57) ABSTRACT

A connector disassembly module is disposed in a casing. The casing includes a bottom board and a side board, wherein the side board includes a first side and a second side on opposite sides. The connector disassembly module includes a first sliding rod, a first rotating rod, and an operating rod. The first sliding rod is disposed on the side board and is movable along a first direction. The first rotating rod is pivotally connected to the bottom board and includes a first driving portion and a second driving portion positioned on opposite sides. The first driving portion is movably connected to the first sliding rod. The operating rod includes a free end and a pivot portion pivotally connected to the side board at a position relatively close to the first side and relatively away from the second side. The operating rod is movably connected to the first sliding rod.

### CROSS REFERENCE TO RELATED APPLICATION

This application claims the priority benefit of Chinese Patent Application No. 202510347572.5, filed on Mar. 21, 2025. The entirety of the mentioned above patent application is hereby incorporated by reference herein and made a part of this specification.

### BACKGROUND OF THE INVENTION

### 1. Field of the Invention

The present invention relates to a connector disassembly module and a server. More specifically, the present invention relates to a connector disassembly module which can be operated to securely connect or remove the connector and a server having said connector disassembly module.

### 2. Description of the Prior Art

With the rapid development of technology, electronic devices such as servers, desktop computers, and data interchange devices are increasingly adopting modular designs. However, due to space limitations, the assembly and disassembly of modules and connectors inside their casings appear to be inconvenient.

Taking the conventional 2U server module as an example, the front of the server typically has two layers. The top layer is used for setting up different modules, while the bottom layer has a Y-shaped cable connecting the modules on the left and right sides. Since the cable connection is located at the front of the first layer and the entire module cannot be easily removed from the casing, both assembly and disassembly become extremely difficult. Therefore, there is a need for a mechanical structure that allows for the quick installation and removal of cables inside the casing. It would be even better if the mechanical structure also provides effort-saving and anti-loosening functions.

### SUMMARY OF THE INVENTION

A purpose of the present invention is to provide a connector disassembly module which can be operated to securely connect or remove the connector in an efficient and convenient manner.

Another purpose of the present invention is to provide a server which can be operated to securely connect or remove the connector in an efficient and convenient manner.

The connector disassembly module of the present invention is disposed in a casing. The casing includes a bottom board and a side board, wherein the side board is disposed perpendicular to the bottom board and includes a first side and a second side on opposite sides. The connector disassembly module includes a first sliding rod, a first rotating rod, and an operating rod. The first sliding rod is disposed on the side board and is movable along a first direction. The first rotating rod is pivotally connected to the bottom board and includes a first driving portion and a second driving portion. The first driving portion and the second driving portion are positioned on opposite sides of the first rotating rod. The first driving portion is movably connected to the first sliding rod. The operating rod includes a free end and a pivot portion, wherein the pivot portion is pivotally connected to the side board at a position relatively close to the first side and relatively away from the second side. The operating rod is movably connected to the first sliding rod. The operating rod is rotatable to move the free end away from the second side, driving the first sliding rod and rotating the first rotating rod to move the second driving portion further away from the first side.

In an embodiment, the first sliding rod includes a first end and a second end positioned at opposite ends respectively close to the first side and the second side. The first sliding rod has a first bump close to the first end and protruding from the first sliding rod in the direction away from the side board. The portion of the first sliding rod close to the second end forms a bent piece bent away from the side board with a gap between the bent piece and the side board. An upper edge of the bent piece forms a recess, and the side of the recess close to the first end forms a recess ramp. The bent piece has a second bump protruding from the bent piece toward the side board and located in the gap, wherein the second bump is close to the side of the recess near the second end. The bent piece has a third bump protruding from a lower edge of the bent piece toward the bottom board. The first driving portion includes a first guide slot, wherein the third bump is movably disposed in the first guide slot. The operating rod includes a guide groove, wherein the first bump is movably disposed in the guide groove.

In an embodiment, the connector disassembly module further includes a limiting module disposed on the side board and movable along the first direction. The limiting module includes a limiting portion relatively close to the second side and relatively away from the first side.

In an embodiment, the connector disassembly module further includes a second rotating rod pivotally connected to the side board at a position corresponding to the recess. The second rotating rod includes a first wing and a second wing positioned on opposite sides of the second rotating rod. The first wing is close to the recess ramp, and the second wing includes a cam extending from the side of the second wing close to the side board toward the bottom board, wherein the cam is movable to enter the gap. When the free end is located relatively close to the second side, the recess ramp abuts an edge of the first wing to keep the first wing away from the bottom board and the second wing close to the bottom board; when the operating rod rotates to move the free end relatively away from the second side, the operating rod drives the first sliding rod to move, then the second bump abuts the cam to keep the second wing away from the bottom board, causing an edge of the second wing to fit into the limiting portion.

In an embodiment, the connector disassembly module further includes a first elastic component connected to the limiting module and the side board, providing elasticity to move the limiting module toward the first side. When the operating rod rotates to move the free end relatively away from the second side, the limiting module is moved toward the first side.

In an embodiment, the limiting module includes a supporting component, a second sliding rod, and a third sliding rod. The supporting component is disposed on the side board and includes a supporting wall parallel to the bottom board. The second sliding rod is movably disposed on the side of the supporting wall facing the bottom board, and a side of the second sliding rod abuts the operating rod. The third sliding rod is movably disposed on the side of the supporting wall facing the bottom board, and the third sliding rod abuts the other side of the second sliding rod relative to the operating rod. The limiting portion is a hook portion extending from the end of the third sliding rod close to the second sliding rod toward the bottom board. The first elastic component is connected to the third sliding rod and the supporting wall.

In an embodiment, the limiting module includes a supporting component and a fourth sliding rod. The supporting component is disposed on the side board and includes a supporting wall parallel to the bottom board. The fourth sliding rod is movably disposed on the side of the supporting wall facing the bottom board, and a side of the fourth sliding rod abuts the operating rod. The limiting portion is a hook portion extending from the end of the fourth sliding rod away from the first side toward the bottom board. The first elastic component is connected to the fourth sliding rod and the supporting wall.

In an embodiment, the limiting module further includes an elastic piece disposed on the side of the supporting wall facing the bottom board, and the elastic piece is facing the first wing. When the elastic piece abuts the first wing, the elastic piece applies force to the first wing, bringing the first wing close to the bottom board and the second wing away from the bottom board.

In an embodiment, the connector disassembly module further includes a stopping bump disposed on the side board. The limiting module is movable toward the first side until abutting the stopping bump.

In an embodiment, the first sliding rod includes a first end and a second end at opposite ends respectively close to the first side and the second side. The first sliding rod has a first bump close to the first end and protruding from the first sliding rod in the direction away from the side board. An upper edge of the portion of the first sliding rod close to the first end forms a recess, and the side of the recess close to the first end forms a recess ramp. The first sliding rod has a third bump close to the second end and protruding from a lower edge of the first sliding rod toward the bottom board. The first driving portion includes a first guide slot, wherein the third bump is movably disposed in the first guide slot. The operating rod includes a guide groove, wherein the first bump is movably disposed in the guide groove.

In an embodiment, the limiting module includes a supporting component and a fifth sliding rod. The supporting component is disposed on the side board and includes a supporting wall parallel to the bottom board. The fifth sliding rod is movably disposed on the side of the supporting wall facing the bottom board. A side of the fifth sliding rod is pivotally connected to the operating rod, and another side of the fifth sliding rod includes an elastic portion bent toward the bottom board, wherein the limiting portion is a hook portion extending from the end of the elastic portion away from the first side toward the bottom board.

In an embodiment, the elastic portion deforms to generate restoring elastic force.

In an embodiment, the side board further includes a positioning bump. The operating rod includes an operating rod body and a positioning component. The operating rod body is pivotally connected to the side board. The positioning component is movably disposed on the side of the operating rod body facing the side board and is partially exposed relative to the operating rod body. An end of the positioning component includes a positioning groove, wherein the positioning groove is engageable with the positioning bump.

In an embodiment, the connector disassembly module further includes a second elastic component connected to the first sliding rod and the side board, providing elastic force to move the first sliding rod toward the second side.

The server of the present invention includes a casing, a plug unit, a module, a first sliding rod, a first rotating rod, and an operating rod. The casing includes a bottom board and a side board, wherein the side board is disposed perpendicular to the bottom board and includes a first side and a second side on opposite sides. The plug unit is disposed on the bottom board and coupled to a cable. The module is disposed on the bottom board and close to the plug unit. The first sliding rod is disposed on the side board and movable along a first direction. The first rotating rod is pivotally connected to the bottom board and includes a first driving portion and a second driving portion. The first driving portion and the second driving portion are positioned on opposite sides of the first rotating rod. The first driving portion and the second driving portion are respectively movably connected to the first sliding rod and the module. The operating rod includes a free end and a pivot portion, wherein the pivot portion is pivotally connected to the side board at a position relatively close to the first side and relatively away from the second side. The operating rod is movably connected to the first sliding rod. The operating rod is rotatable to move the free end away from the second side, driving the first sliding rod and rotating the first rotating rod to move the second driving portion further away from the plug unit.

### BRIEF DESCRIPTION OF THE DRAWINGS

FIG. 1 is a schematic diagram of an embodiment of a connector disassembly module disposed in a casing in the present invention.

FIG. 2 is a schematic diagram of the relative positions of a connector disassembly module and the bottom board and the side board in a casing of the present invention.

FIG. 3 is an exploded view of an embodiment of a connector disassembly module of the present invention.

FIGS. 4A and 4B respectively show schematic diagrams of an embodiment of an operating rod before and after stretching the elastic component of the present invention.

FIG. 5A is an exploded view of an embodiment of a first sliding rod in a connector disassembly module of the present invention.

FIG. 5B is a schematic diagram of the position of a first sliding rod and a second rotating rod in a connector disassembly module of the present invention.

FIGS. 6A and 6B are schematic diagrams of an embodiment of an operating rod with the free end relatively close to a second side in the present invention.

FIGS. 7A and 7B are schematic diagrams of an embodiment of an operating rod during rotation in the present invention.

FIGS. 8A and 8B are schematic diagrams of an embodiment of an operating rod with the free end relatively away from a second side in the present invention.

FIG. 9 is an exploded view of an embodiment of a limiting module in the present invention.

FIGS. 10A and 10B are operational diagrams of an embodiment of a limiting module in the present invention.

FIG. 11A and 11B are schematic diagrams of an embodiment of a limiting module when the operating rod is in the position with the free end relatively close to a second side in the present invention.

FIG. 12 is a schematic diagram of the position of a second driving portion when the operating rod is in the position with the free end relatively close to a second side in the present invention.

FIGS. 13A and 13B are schematic diagrams of an embodiment of a limiting module when the operating rod is in the position with the free end relatively away from a second side in the present invention.

FIG. 14 is a schematic diagram of the position of a second driving portion when the operating rod is in the position with the free end relatively away from a second side in the present invention.

FIGS. 15A and 15B are schematic diagrams of an embodiment of a limiting module when the operating rod is in the position with the free end relatively further away from a second side in the present invention.

FIG. 16 is a schematic diagram of the position of a second driving portion when the operating rod is in the position with the free end relatively further away from a second side in the present invention.

FIG. 17 is a schematic diagram of the position of a positioning groove and a positioning bump engaged with each other in the present invention.

FIG. 18 is an exploded view of another embodiment of a limiting module in a connector disassembly module of the present invention.

FIGS. 19A and 19B are operational diagrams of another embodiment of a limiting module in a connector disassembly module of the present invention.

FIG. 20 is an exploded view of another embodiment of a limiting module in a connector disassembly module of the present invention.

FIGS. 21A and 21B are operational diagrams of another embodiment of a limiting module in a connector disassembly module of the present invention.

### DETAILED DESCRIPTION OF THE INVENTION

The connecting component disclosed by the present invention will be described in detail below through specific embodiments and with reference to the drawings. A person having ordinary skill in the present art can understand the advantages and effects of the present invention from the contents disclosed in this specification. However, the contents disclosed below are not limiting to the scope of the present invention. A person having ordinary skill in the art can implement the invention in different embodiments based on various perspectives and applications without departing from the spirit of the present invention. In the attached figures, for the purpose of clarification, the thicknesses of layers, films, panels, regions and the like are amplified. In the whole specification, the same marks represent the same element. It should be understood that, when an element such as a layer, a film, a panel, a region or a substrate is described as “being on” or “being connected to” another element, it may be directly on or connected to another element, or there may be other elements therebetween. On the other hand, when an element is described as “directly existing on another element” or “being directly connected to” another element, there is no element therebetween. As used in the present specification, a “connection” may be a physical and/or electrical connection. In addition, an “electrical connection” or “coupling” means that other elements may exist therebetween.

It should be understood that, even though the terms such as “first”, “second”, “third” may be used to describe an element, a part, a region, a layer and/or a portion in the present specification, but these elements, parts, regions, layers and/or portions are not limited by such terms. Such terms are merely used to differentiate an element, a part, a region, a layer and/or a portion from another element, part, region, layer and/or portion. Therefore, in the following discussions, a first element, portion, region, layer or portion may be called a second element, portion, region, layer or portion, and do not depart from the teaching of the present invention.

In addition, relative terms such as ”lower” or ”bottom” and “on” or ”top” may be used to describe the relationship between an element and another element in the present specification, as shown in the figures. It should be understood that, the purpose of using relative terms is to include the different directions of the devices not shown in the figures. For example, if a device in an attached figure is turned upside down, an element described as being “under“ another element will be “on top of” that element. Therefore, a descriptive term “under” may include the meaning of both ”under” and “on top of”, depending on the specific orientation of the attached figure.

The terms “about”, “approximate” or “essentially” used in the present specification include the value itself and the average values within the acceptable range of deviation of the specific values confirmed by a person having ordinary skill in the present art, considering the specific measurement discussed and the number of errors related to such measurement (that is, the limitation of the measurement system). For example, “about” may mean within one or more standard deviations of the value itself, or within ±30%, ±20%, ±10%, ±5%. In addition, “about”, “approximate” or “essentially” used in the present specification may select a more acceptable range of deviation or standard deviation based on optical property, etching property or other properties. One cannot apply one standard deviation to all properties.

In the present invention, a rear casing of a display device is provided to be used together with a display module and a middle frame of the display module. In an embodiment, the display module includes a display panel and the middle frame, wherein the middle frame surrounds the display panel. The term “surround” also covers the situation where the middle frame is disposed under the display panel and distributed along the sides of the display panel. For ease of explanation, in the below embodiments, the rear casing of the display device is regarded as being positioned on a plane, and the display module is disposed on the rear casing of the display device. That is, the rear casing of the display device and the display module are respectively located on the lower and upper positions. The term “upper” refers to being close to the display module and away from the plane, and the term “lower” refers to being close to the plane and away from the display module.

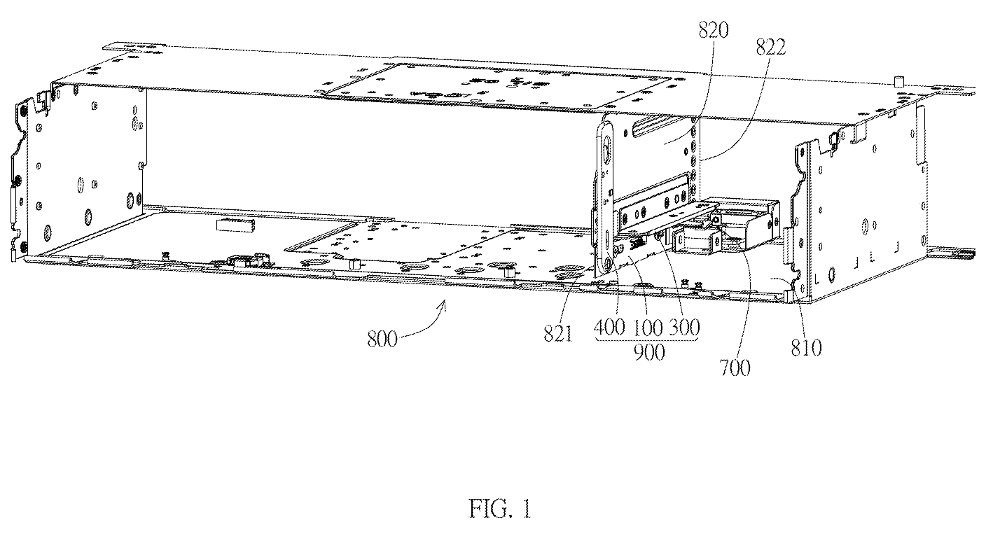

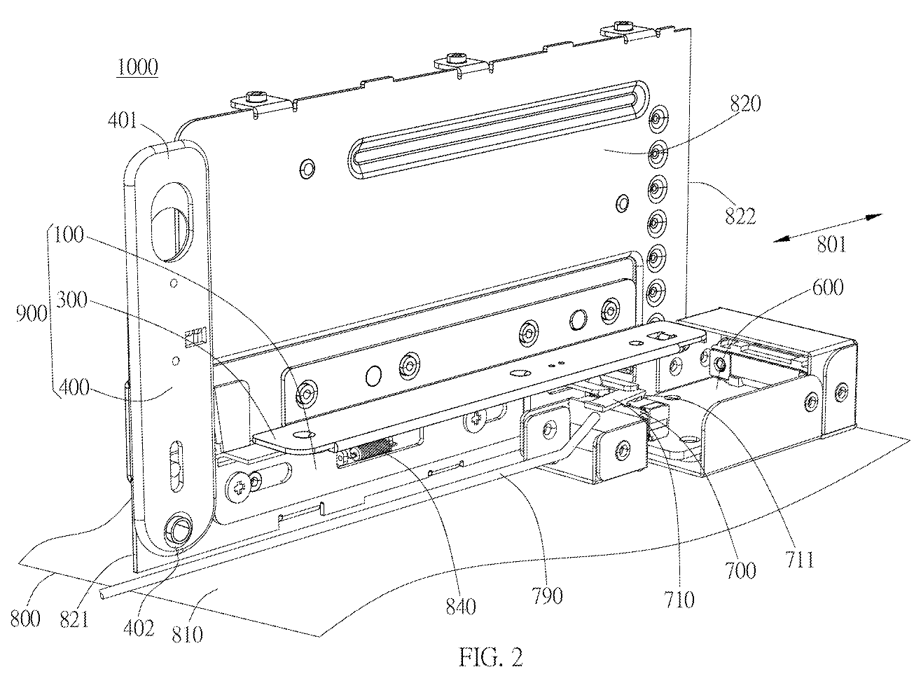

In the embodiment shown in FIGS. 1 and 2, a connector disassembly module 900 of the present invention is disposed in a casing 800 of an electronic device, for example, a server, a desktop computer, a data switch, and the like, and is designed for use with a plug unit 700 such as a signal plug. The casing 800 includes a bottom board 810 and a side board 820, wherein the side board 820 is disposed perpendicular to the bottom board 810 and includes a first side 821 and a second side 822 on opposite sides. Furthermore, in the embodiment shown in FIG. 2, the casing 800, the plug unit 700, the module 600, and the connector disassembly module 900 can form a server 1000 of the present invention. The module 600 may be, for example, a pluggable module or an expansion module (such as an Open Compute Project (OCP) module). The plug unit 700 may be, for example, a signal plug disposed on the bottom board 810 and coupled to a cable 790. The module 600 is disposed on the bottom board 810 and close to the plug unit 700, wherein the module 600 may be connected to a functional unit such as a connector.

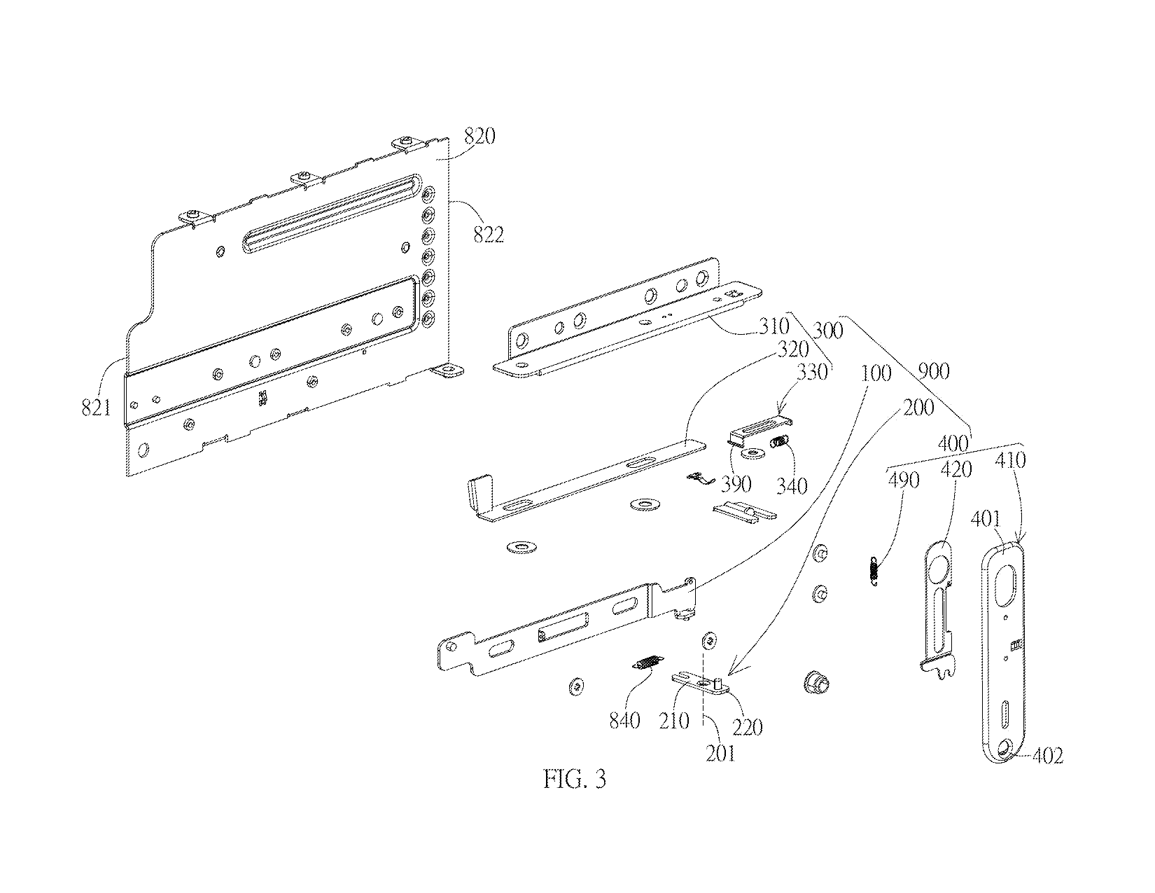

In the embodiment shown in FIG. 3, the connector disassembly module 900 includes a first sliding rod 100, a first rotating rod 200, and an operating rod 400. The first sliding rod 100 is disposed on the side board 820 and is movable along, for example, a first direction 801 parallel to the bottom board 810 (referring to FIG. 2). A second elastic component 840 may be connected to the first sliding rod 100 and the side board 820 to provide elastic force to return the first sliding rod 100 to its original position when moving along the first direction 801. For example, after the first sliding rod 100 is pulled to the first side and released, the second elastic component 840 enables the first sliding rod 100 to move backward to the second side. The connector disassembly module 900 may further include a limiting module 300, wherein the limiting module 300 is disposed on the side board 820, preferably above the first sliding rod 100, and is movable along the first direction 801. The limiting module 300 includes a limiting portion 390 disposed relatively close to the second side 822 and relatively away from the first side 821. The operating rod 400 includes a free end 401 and a pivot portion 402, wherein the pivot portion 402 is pivotally connected to the side board 820 at a position relatively close to the first side 821 and relatively away from the second side 822. The operating rod 400 is movably connected to the first sliding rod 100.

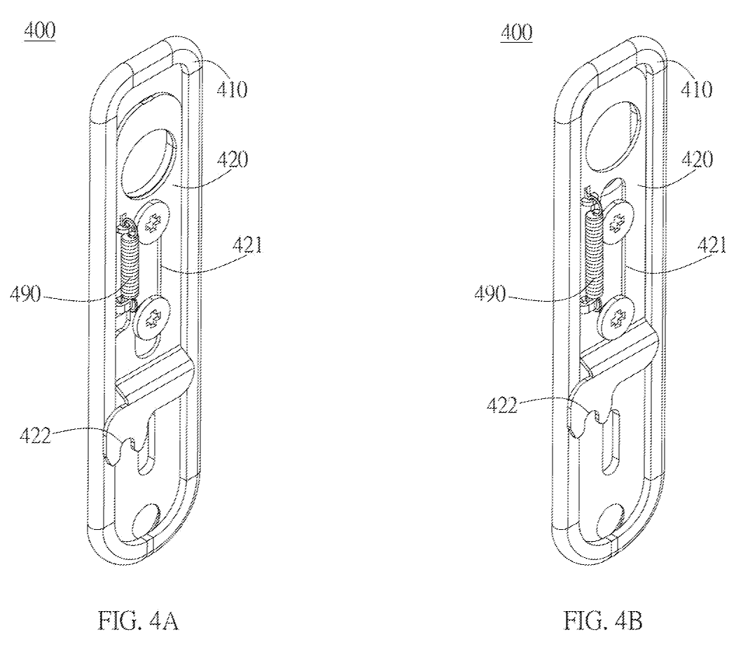

More specifically, in the embodiment shown in FIGS. 4A and 4B, the operating rod 400 includes an operating rod body 410 and a positioning component 420. The operating rod body 410 is pivotally connected to the side board 820 (referring to FIG. 3), and the positioning component 420 includes a guide slot 421. By using, for example, a screw to fasten the positioning component 420 to the operating rod body 410 through the guide slot 421, the positioning component 420 is movably disposed on the side of the operating rod body 410 facing the side board 820 and may be partially exposed through the operating rod body 410 from the other side facing away from the side board 820. In this embodiment, the operating rod body 410 includes an operating hole, wherein the positioning component 420 may be partially exposed through the operating hole. Furthermore, a user can contact the positioning component 420 through the operating hole to control the movement of the positioning component 420 on the operating rod body 410. In another embodiment, the positioning component 420 may protrude outward from the edge of the operating rod body 410. In addition, the operating rod 400 may include a third elastic component 490 connected to the operating rod body 410 and the positioning component 420. When the positioning component 420 moves from the position shown in FIG. 4A to the position shown in FIG. 4B, the third elastic component 490 is stretched and generates a restoring elastic force. The positioning component 420 can move from the position shown in FIG. 4B back to the position shown in FIG. 4A by this restoring elastic force.

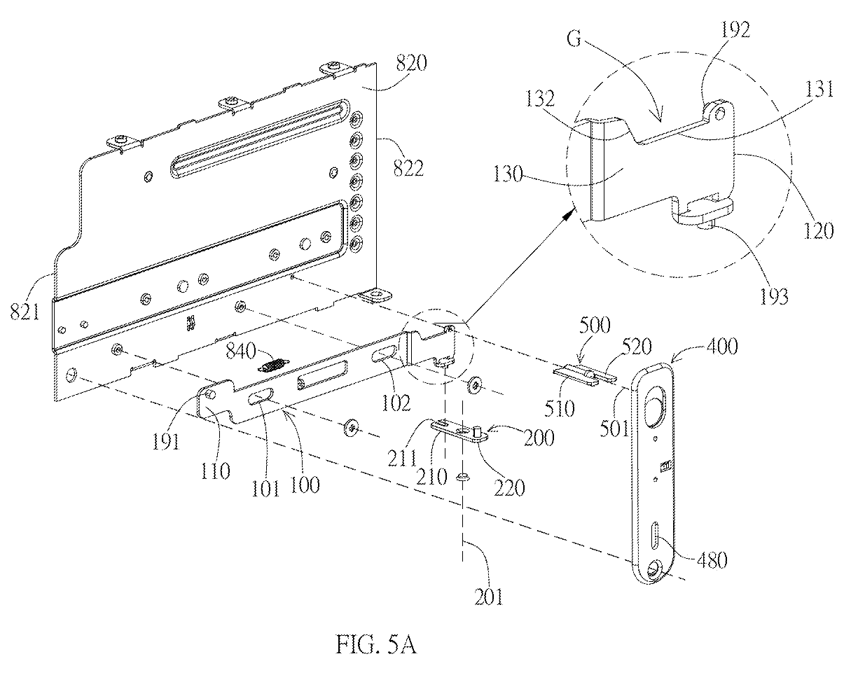

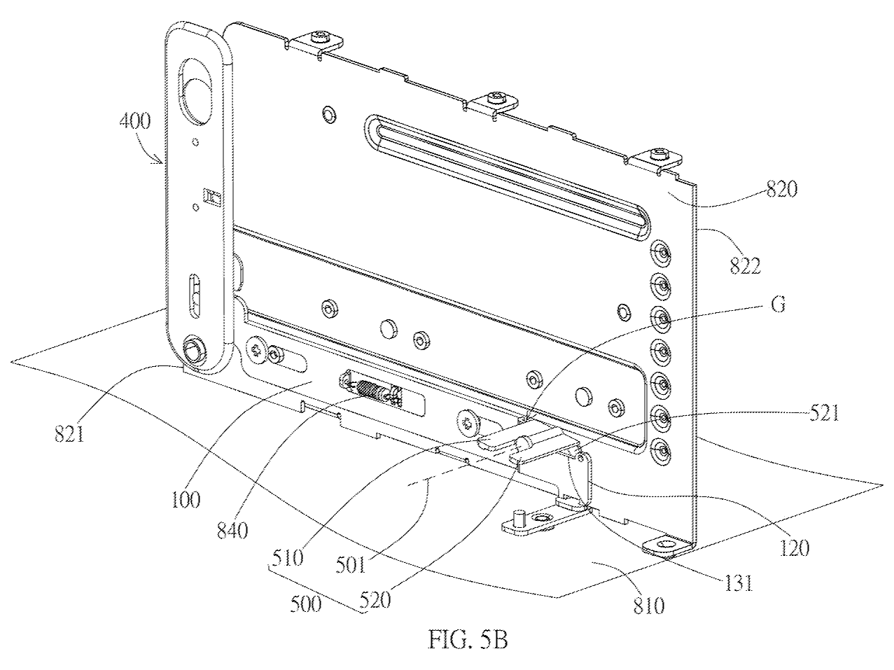

In the embodiment shown in FIGS. 5A and 5B, the first sliding rod 100 includes guide slots 101 and 102 extending parallel to the bottom board 810 (referring to FIG. 5B). By using, for example, screws to fasten the first sliding rod 100 on the side board 820 through the guide slots 101 and 102, the first sliding rod 100 is movable parallel to the bottom board 810. The first rotating rod 200 is pivotally connected to the bottom board 810 and includes a first driving portion 210 and a second driving portion 220. The first driving portion 210 and the second driving portion 220 are on opposite sides of the first rotating rod 200, for example, on opposite sides of a rotation axis 201 of the first rotating rod 200, wherein the first driving portion 210 is movably connected to the first sliding rod 100.

More specifically, in the embodiment shown in FIG. 5A, the first sliding rod 100 includes a first end 110 and a second end 120 positioned on opposite ends respectively close to the first side 821 and the second side 822. The first sliding rod 100 has a first bump 191 close to the first end 110 and protruding from the first sliding rod 100 in the direction away from the side board 820. A portion of the first sliding rod 100 close to the second end 120 forms a bent piece 130 bent away from the side board 820 with a gap G between the bent piece 130 and the side board 820, wherein the upper edge of the bent piece 130 forms a recess 131, and a side of the recess 131 close to the first end 110 forms a recess ramp 132. The bent piece 130 has a second bump 192 protruding from the bent piece 130 toward the side board 820 and located in the gap G, wherein the second bump 192 is close to a side of the recess 131 near the second end 120. The bent piece 130 has a third bump 193 protruding from a lower edge of the bent piece 130 toward the bottom board 810 (referring to FIG. 5B).

In the embodiment shown in FIG. 5A, the first driving portion 210 includes a first guide slot 211, wherein the third bump 193 is movably disposed in the first guide slot 211. The operating rod 400 includes a guide groove 480, wherein the first bump 191 is movably disposed in the guide groove 480. In the embodiment shown in FIG. 5B, the second rotating rod 500 is pivotally connected to the side board 820 at a position corresponding to the recess 131. The second rotating rod 500 includes a first wing 510 and a second wing 520 positioned on opposite sides of the second rotating rod 500, for example, on opposite sides of a rotation axis 501 of the second rotating rod 500. The first wing 510 is close to the recess ramp 132 (referring to FIG. 5A), and the second wing 520 includes a cam 521 extending from the side of the second wing 520 close to the side board 820 toward the bottom board 810, wherein the cam 521 is movable to enter the gap G.

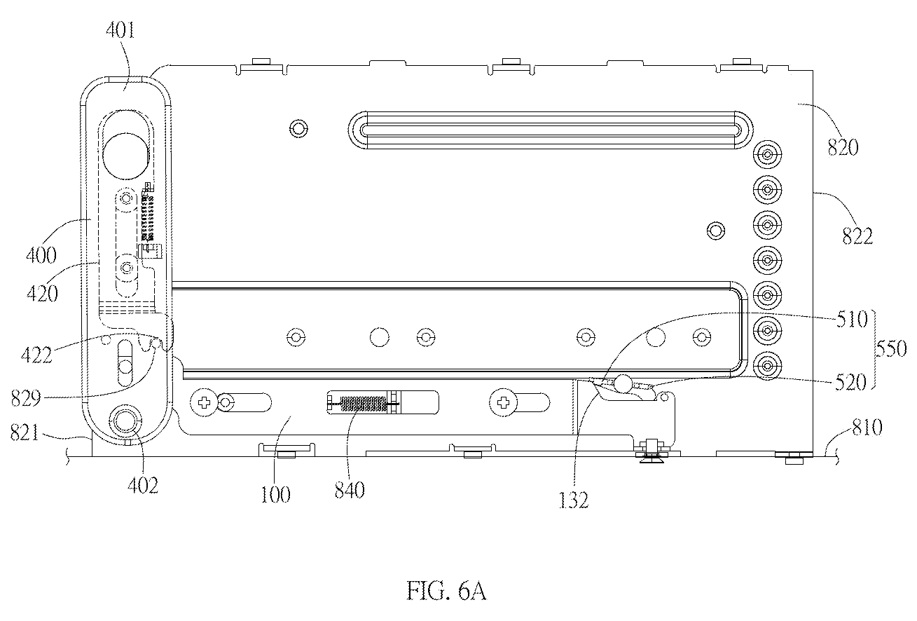

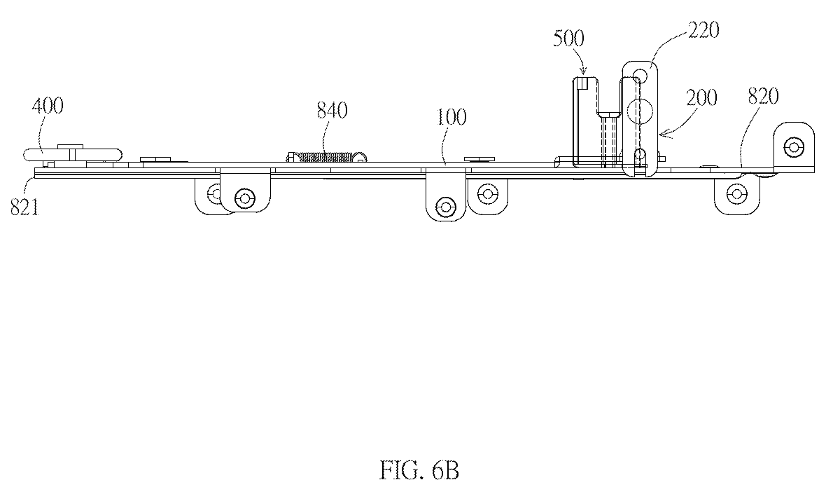

In the embodiment shown in FIG. 6A, an end of the positioning component 420 may include a positioning groove 422, wherein the positioning groove 422 may be engaged with a positioning bump 829 disposed on the side board 820, limiting the rotation of the operating rod 400. In another aspect, based on this configuration, the position of the operating rod 400 is secured, preventing unintended rotation of the operating rod 400. Before rotating the operating rod 400, that is, when the free end 401 is relatively close to the second side 822, the recess ramp 132 abuts an edge of the first wing 510 to keep the first wing 510 away from the bottom board 810 and the second wing 520 close to the bottom board 810. Meanwhile, the second driving portion 220 is located in the position as shown in FIG. 6B.

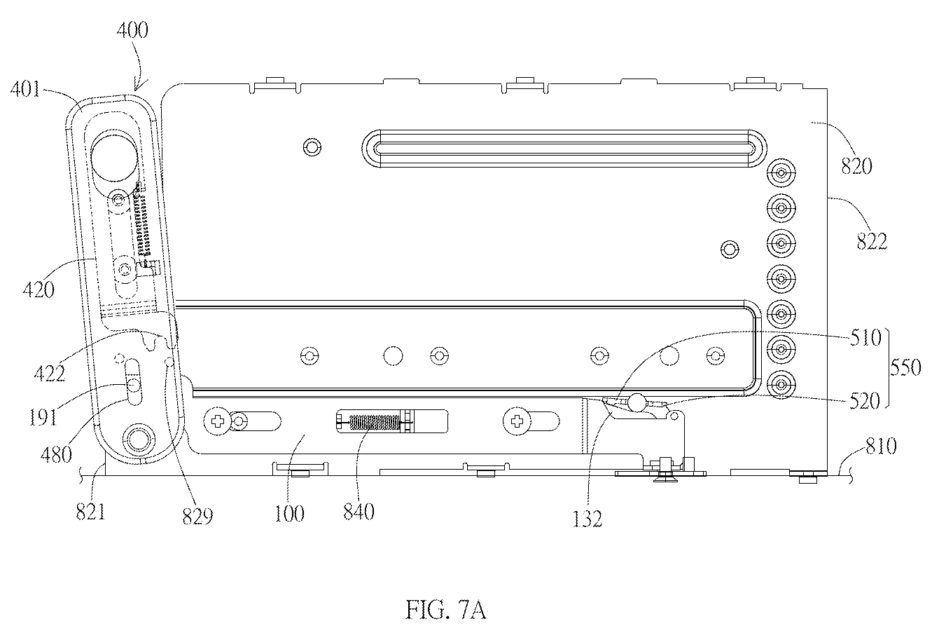

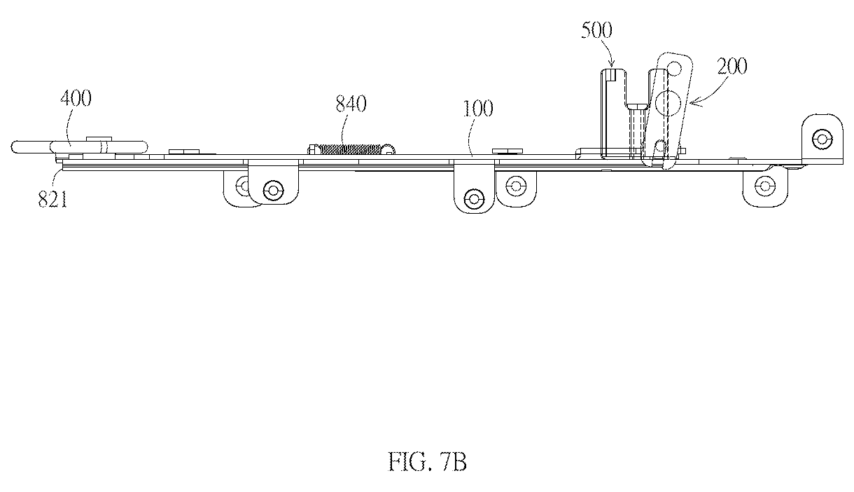

In the embodiment shown in FIG. 7A, when the positioning component 420 moves to make the positioning groove 422 separate from the positioning bump 829, the operating rod 400 can rotate and drive the first sliding rod 100 to move by using the first bump 191 disposed in the guide groove 480. In the meantime, in the embodiment shown in FIG. 7B, by using the third bump 193 disposed in the first guide slot 211 (referring to FIG. 5A), the first sliding rod 100 further drives the first rotating rod 200 to rotate.

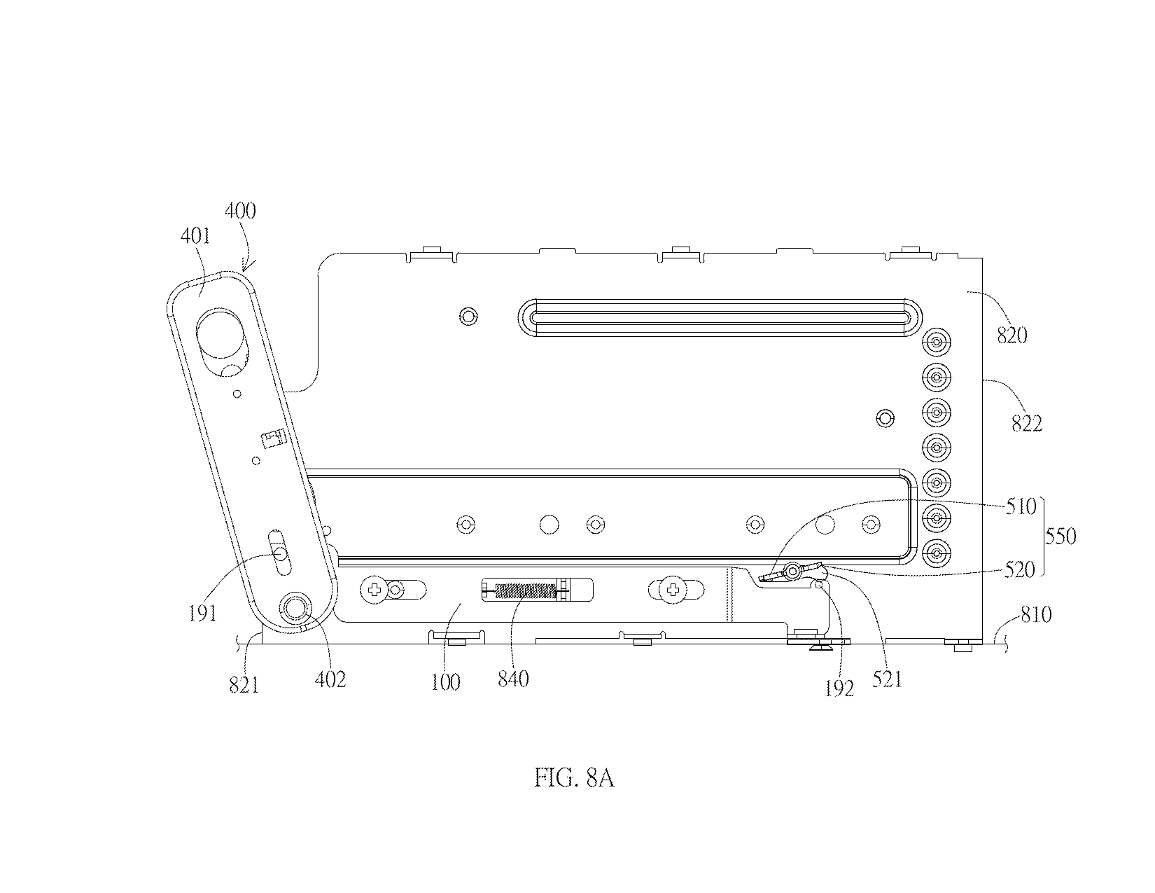

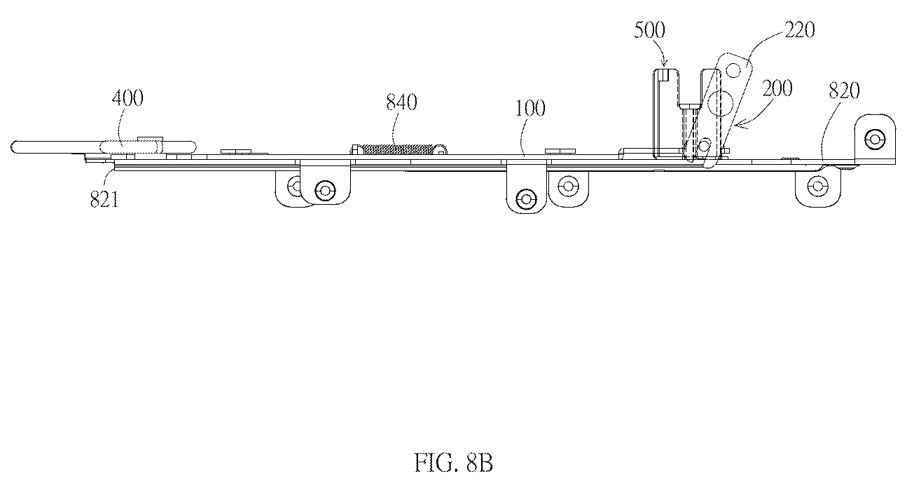

In the embodiment shown in FIG. 8A, when the operating rod 400 rotates to move the free end 401 relatively away from the second side 822, the operating rod 400 drives the first sliding rod 100 to move, causing the second bump 192 to abut the cam 521 to keep the second wing 520 away from the bottom board 810. Meanwhile, the first sliding rod 100 drives the first rotating rod 200 to rotate, moving the second driving portion 220 into the position as shown in FIG. 8B.

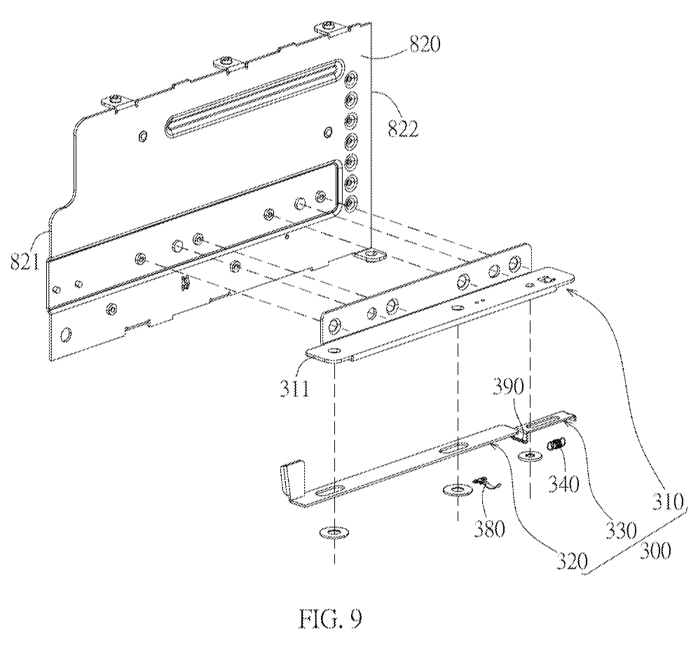

In the embodiment shown in FIG. 9, the limiting module 300 includes a supporting component 310, a second sliding rod 320, and a third sliding rod 330. The supporting component 310 is disposed on the side board 820 and includes a supporting wall 311 parallel to the bottom board 810 (referring to FIG. 2). The second sliding rod 320 is movably disposed on the side of the supporting wall 311 facing the bottom board 810, and a side of the second sliding rod 320 may abut the operating rod 400 (referring to FIG. 2). The third sliding rod 330 is movably disposed on the side of the supporting wall 311 facing the bottom board 810, and the third sliding rod 330 abuts the other side of the second sliding rod 320 relative to the operating rod 400. In this embodiment, the limiting portion 390 is a hook portion extending from the end of the third sliding rod 330 close to the second sliding rod 320 toward the bottom board 810 (referring to FIG. 2). The first elastic component 340 is connected to the third sliding rod 330 and the supporting wall 311.

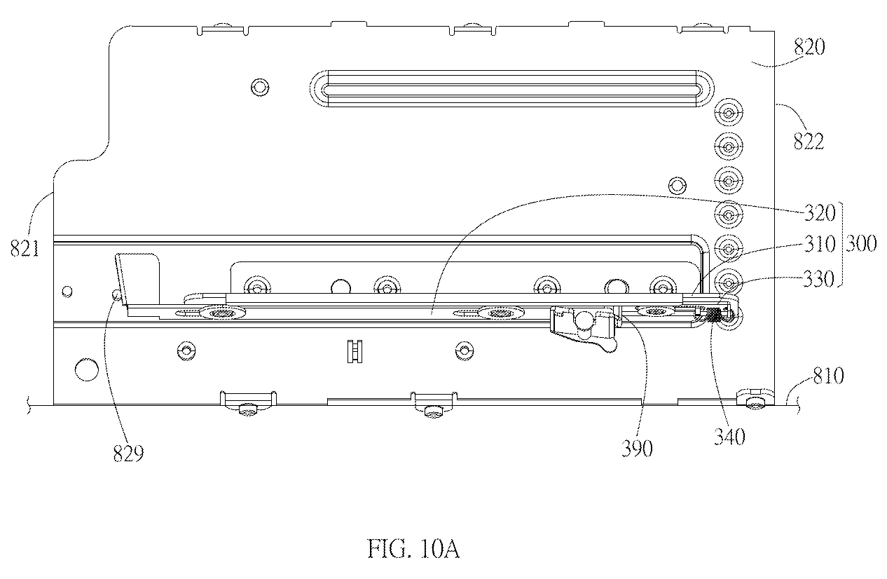

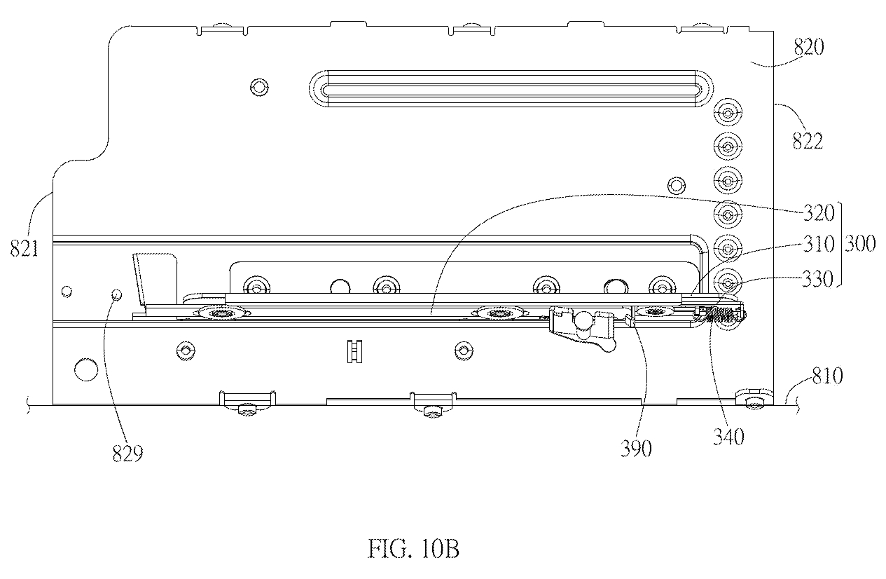

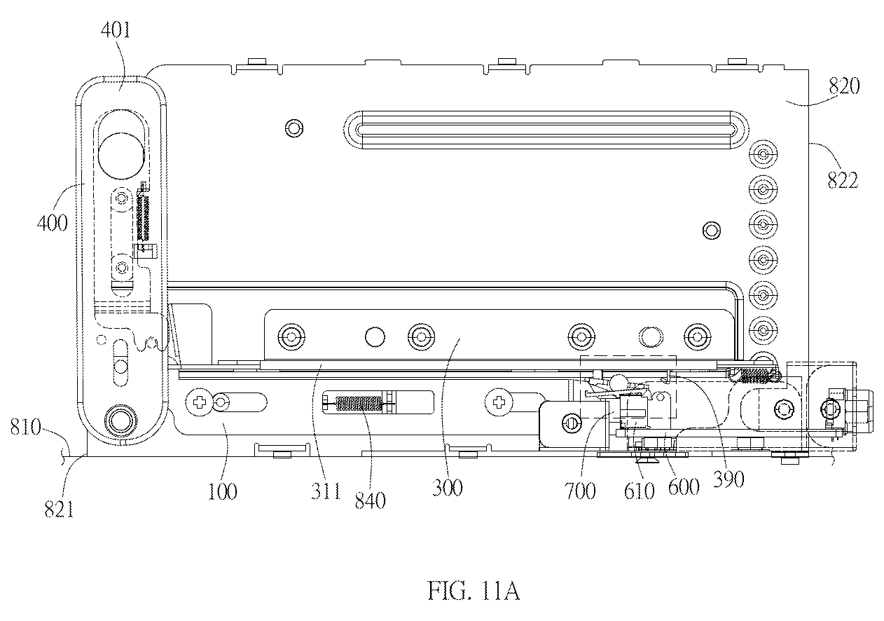

When the third sliding rod 330 moves from the position as shown in FIG. 10A to the position as shown in FIG. 10B, the first elastic component 340 is stretched and generates a restoring elastic force. The third sliding rod 330 can move from the position shown in FIG. 10B back to the position shown in FIG. 10A by this restoring elastic force. In another aspect, the first elastic component 340 generates a restoring elastic force when being stretched to drive the third sliding rod 330 to move toward the first side 821, further pushing the second sliding rod 320, which abuts the third sliding rod 330, to move toward the first side 821. As shown in FIG. 10A, the second sliding rod 320 in the limiting module 300 may move toward the first side 821 until abutting a stopping bump disposed on the side board 820. In this embodiment, the positioning bump 829 may also serve as the stopping bump.

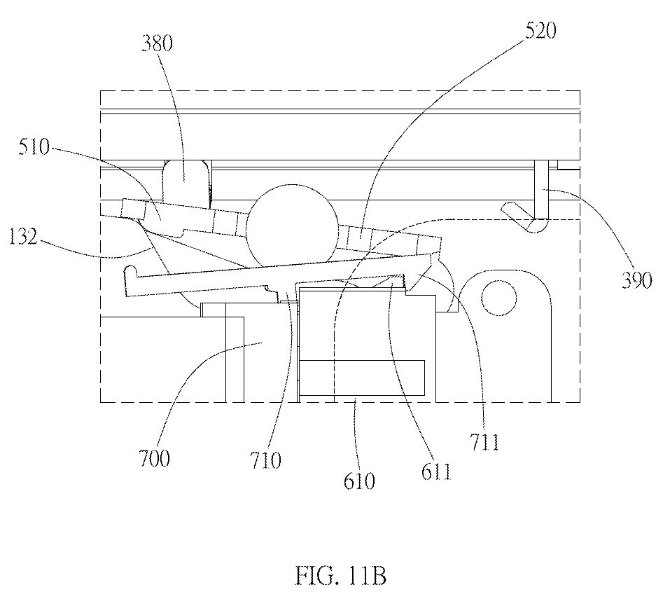

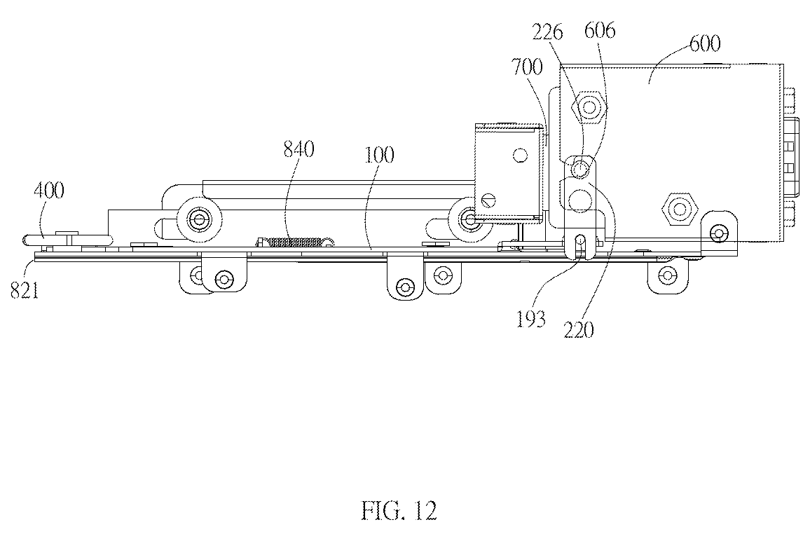

In the embodiment shown in FIGS. 11A and 11B, wherein FIG. 11B is an enlarged view of the dashed frame in FIG. 11A, when the operating rod 400 is at the position with the free end 401 located relatively close to the second side 822, the limiting portion 390 is located at the position as shown in FIG. 11B. The recess ramp 132 abuts an edge of the first wing 510 to keep the first wing 510 away from the bottom board 810 and the second wing 520 close to the bottom board 810. The second wing 520 abuts the side of a holding piece 710 having a hook portion 711 to prevent the holding piece 710 from disengaging from a holding portion 611 of a connector 610 of the module 600 and cause disconnection of the plug unit 700 and the connector 610. In addition, the limiting module 300 further includes an elastic piece 380 disposed on the side of the supporting wall 311 facing the bottom board 810, and the elastic piece 380 is facing the first wing 510. When the elastic piece 380 abuts the first wing 510, the elastic piece 380 can apply force to the first wing 510, bringing the first wing 510 close to the bottom board 810 and the second wing 520 away from the bottom board 810. Meanwhile, the second driving portion 220 is located in the position as shown in FIG. 12, and the plug unit 700 is plugged in the module 600.

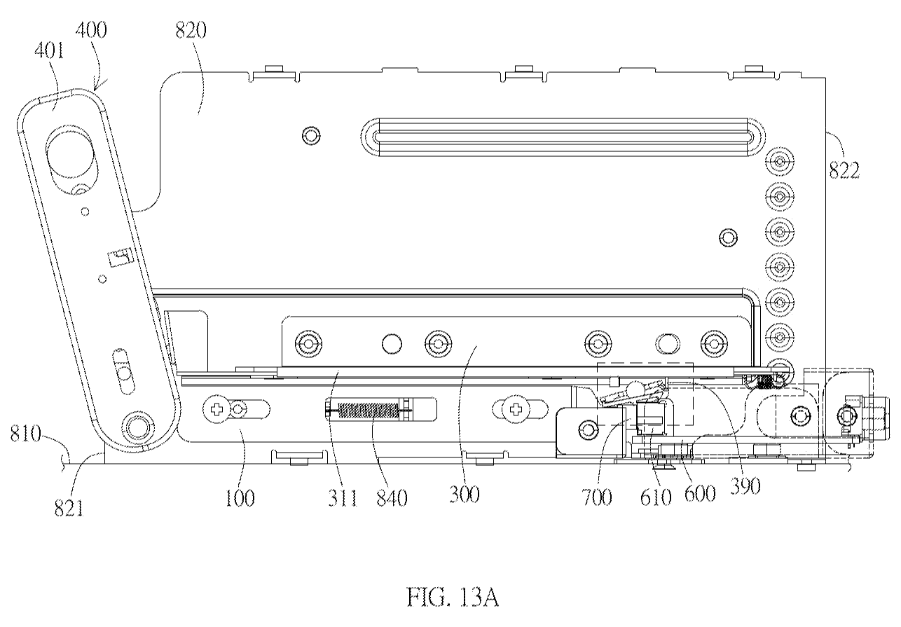

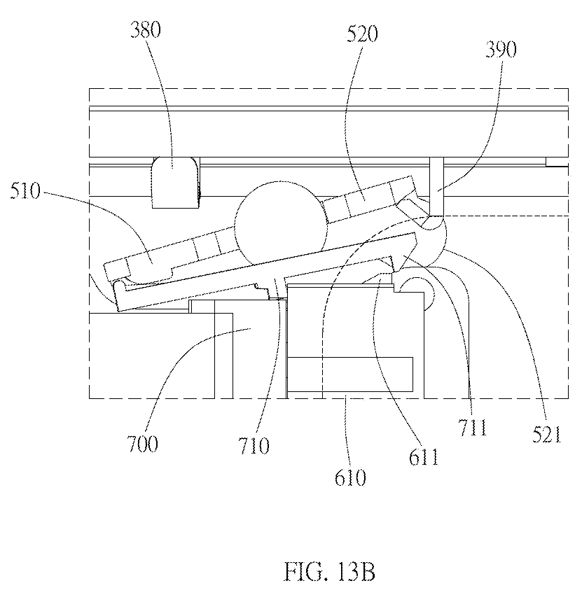

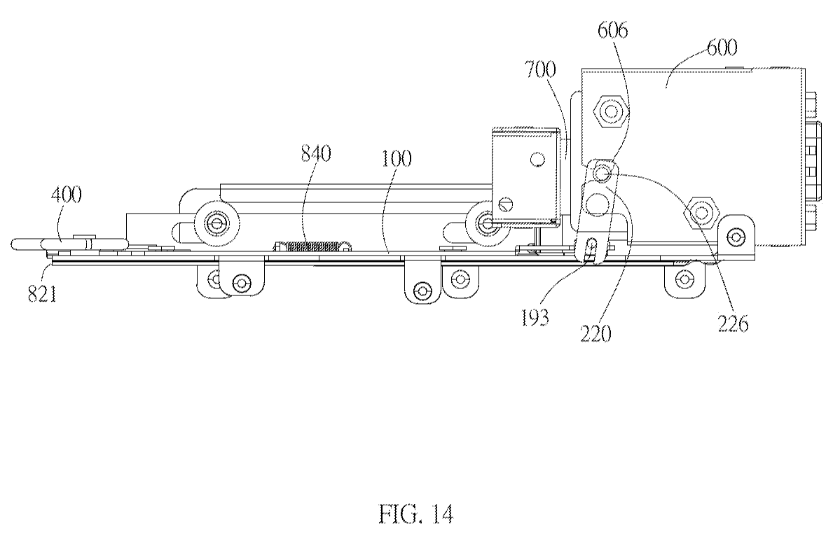

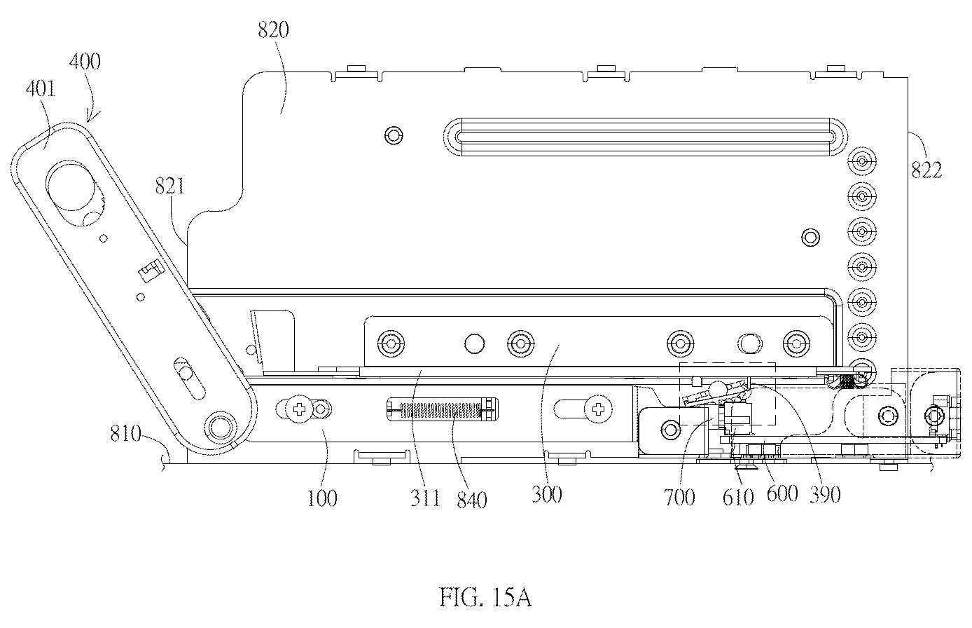

In the embodiment shown in FIGS. 13A and 13B, wherein FIG. 13B is an enlarged view of the dashed frame in FIG. 13A, when the operating rod 400 rotates to move the free end 401 relatively away from the second side 822, the limiting portion 390 is located at the position as shown in FIG. 13B. The operating rod 400 drives the first sliding rod 100 to move, the second bump 192 (referring to FIG. 8A) abuts the cam 521 to keep the second wing 520 away from the bottom board 810, causing an edge of the second wing 520 to fit into the limiting portion 390. Furthermore, the first wing 510 abuts the side of the holding piece 710 without the hook portion 711, causing displacement between the hook portion 711 and the holding portion 611 to disengage them. Meanwhile, the second driving portion 220 is located in the position as shown in FIG. 14, and the plug unit 700 begins to unplug from the module 600.

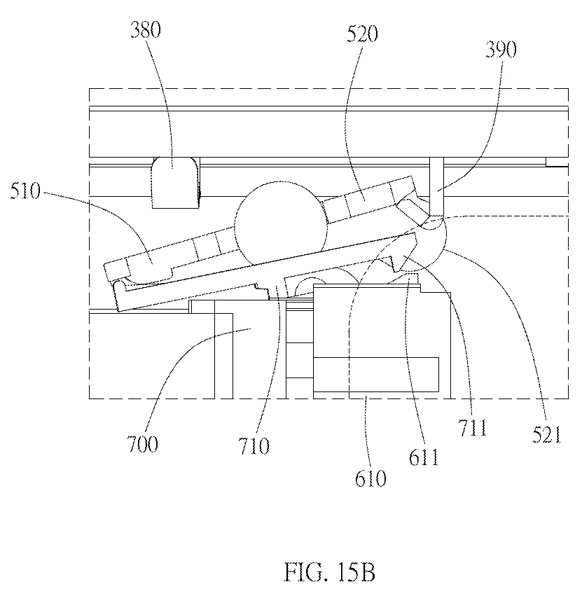

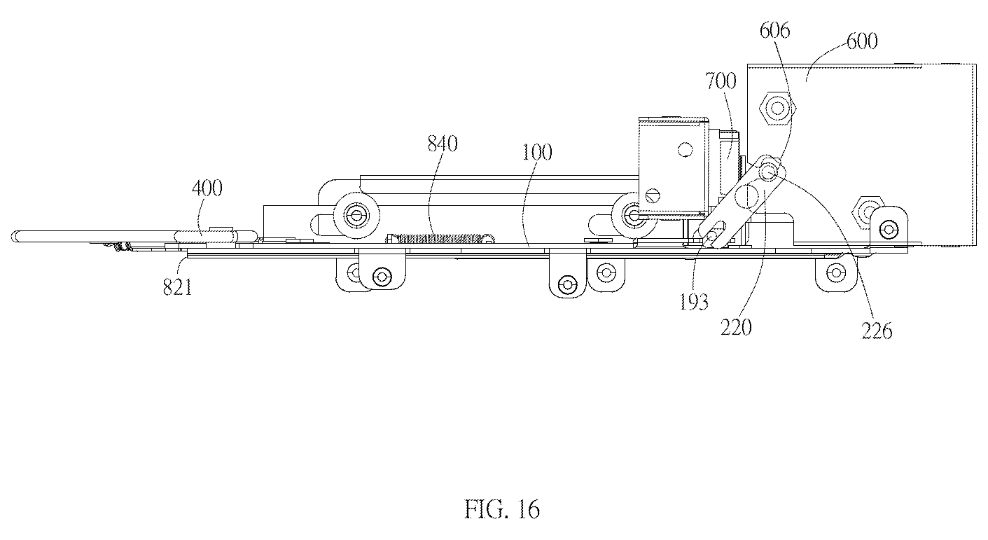

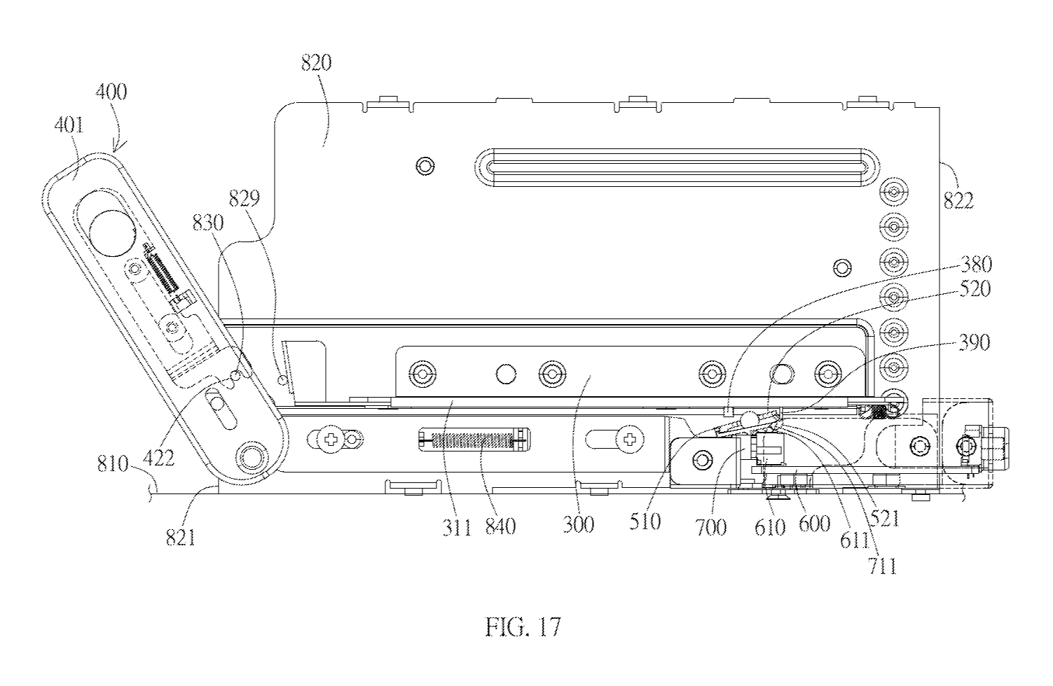

In the embodiment shown in FIGS. 15A and 15B, wherein FIG. 15B is an enlarged view of the dashed frame in FIG. 15A, when the operating rod 400 continues rotating outward to drive the first sliding rod 100 to continue moving toward the first side 821, the limiting portion 390 remains in a matched state with the edge of the second wing 520, as shown in FIG. 15B, and the hook portion 711 remains in a displaced state with the holding portion 611. In the meantime, in the embodiment shown in FIG. 16, the second driving portion 220 moves further away from the first side 821 with the driving force of the third bump 193 of the first sliding rod 100. Moreover, since the second driving portion 220 has a projection 226 inserted into a second guide slot 606 on the bottom of the module 600, the module 600 can be moved further away from the first side 821 (that is, away from the plug unit 700) with the driving force of the second driving portion 220, causing the module 600 and the plug unit 700 to become disconnected. Furthermore, in the embodiment shown in FIG. 17, the positioning groove 422 may be engaged with a positioning bump 830 (relatively closer to the first side 821 compared to the positioning bump 829) disposed on the side board 820, securing the position of the operating rod 400.

In summary, the connector disassembly module of the present invention can operate without additional tools: by applying force to rotate the operating rod, the connector and the module socket can be disconnected; by applying force to push the module and rotate the operating rod, the connection and engagement between the connector and the module socket can be achieved, preventing loosening and facilitating usage and maintenance.

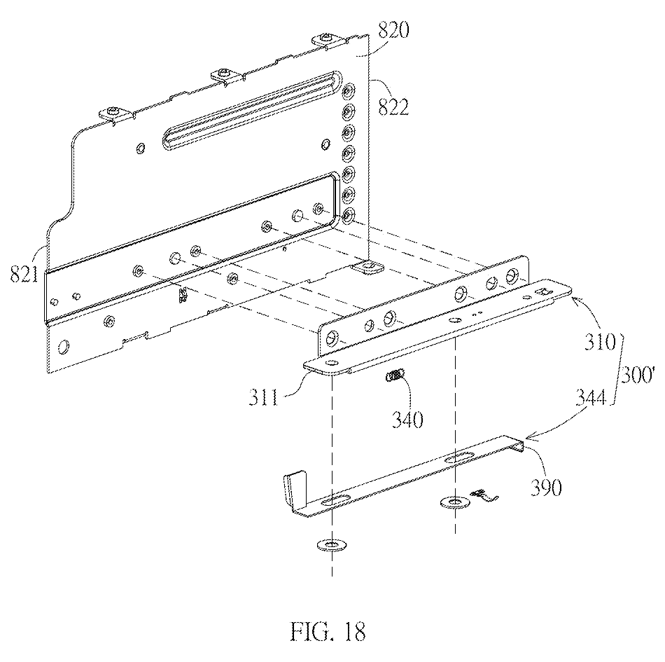

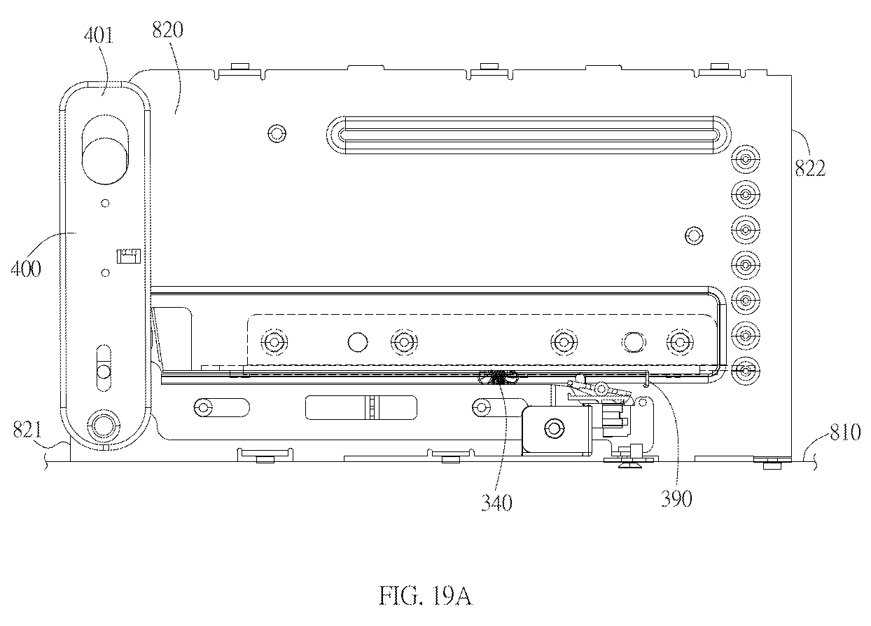

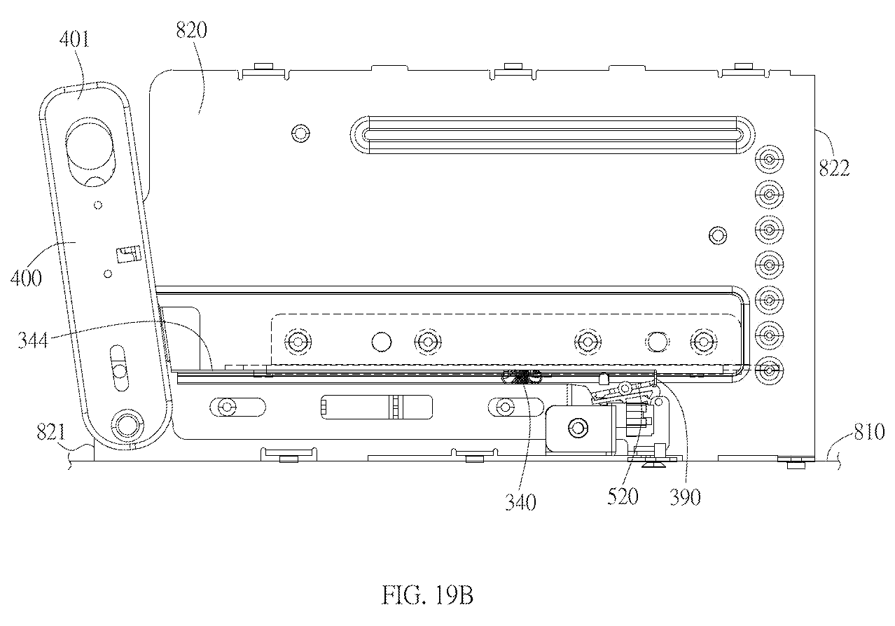

In various embodiments, the limiting module may have different modifications according to the needs. In the embodiment shown in FIG. 18, the limiting module 300’ includes a supporting component 310 and a fourth sliding rod 344. The supporting component 310 is disposed on the side board 820 and includes a supporting wall 311 parallel to the bottom board 810 (referring to FIG. 19A). The fourth sliding rod 344 is movably disposed on the side of the supporting wall 311 facing the bottom board 810, and a side of the fourth sliding rod 344 abuts the operating rod 400 (referring to FIG. 19A). The limiting portion 390 is a hook portion extending from the end of the fourth sliding rod 344 away from the first side 821 toward the bottom board 810. The first elastic component 340 is connected to the fourth sliding rod 344 and the supporting wall 311, providing elastic force to move the fourth sliding rod 344 toward the first side 821. Furthermore, when the operating rod 400 rotates from the position as shown in FIG. 19A to the position as shown in FIG. 19B, the elastic force provided by the first elastic component 340 (referring to FIG. 18) drives the fourth sliding rod 344 to move toward the first side 821, and the limiting portion 390 moves to fit together with an edge of the second wing 520.

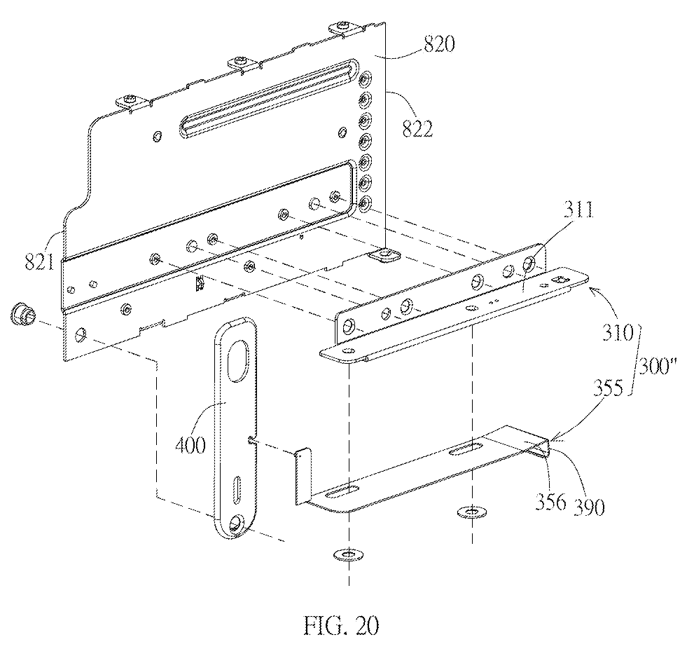

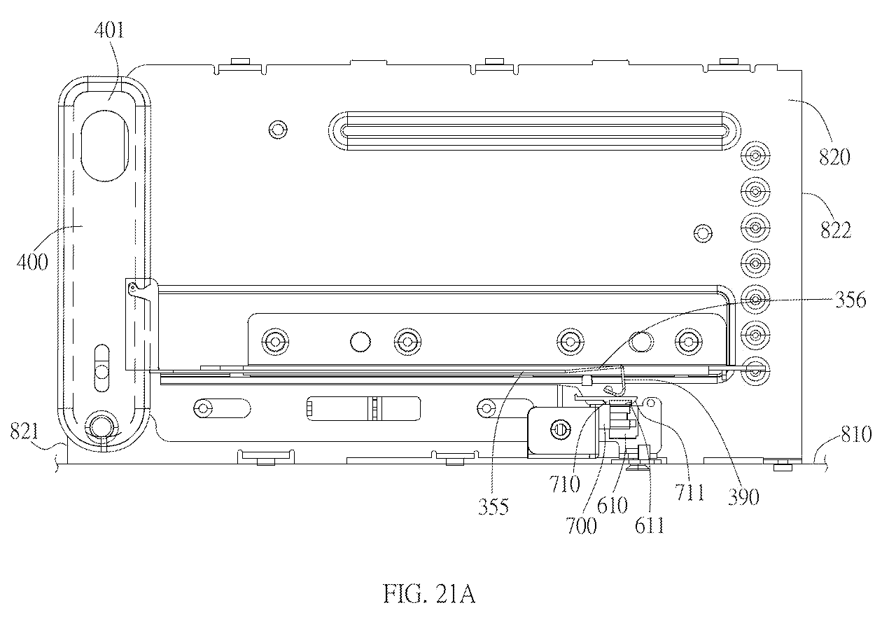

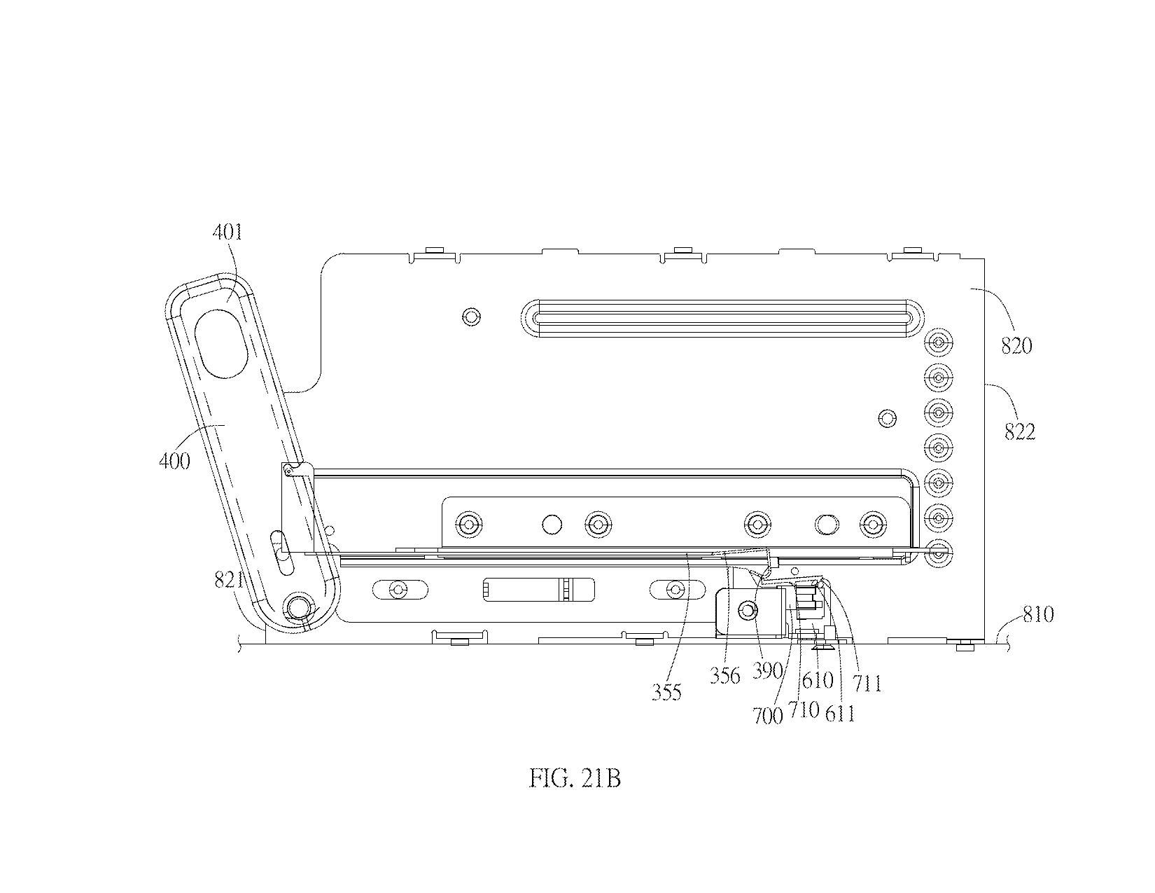

In the embodiment shown in FIG. 20, the limiting module 300’’ includes a supporting component 310 and a fifth sliding rod 355. The supporting component 310 is disposed on the side board 820 and includes a supporting wall 311 parallel to the bottom board 810 (referring to FIG. 21A). The fifth sliding rod 355 is movably disposed on the side of the supporting wall 311 facing the bottom board 810. A side of the fifth sliding rod 355 is pivotally connected to the operating rod 400, and another side of the fifth sliding rod 355 includes an elastic portion 356 bent toward the bottom board 810. A limiting portion 390 is a hook portion extending from the end of the elastic portion 356 away from the first side 821 toward the bottom board 810. The elastic portion 356 can deform to generate a restoring elastic force.

In the embodiment shown in FIG. 21A, when the operating rod 400 is at the position with the free end 401 located relatively close to the second side 822, the limiting portion 390 is located above the side of the holding piece 710 with the hook portion 711. The elastic portion 356 provides a restoring elastic force to abut the side of the holding piece 710 with the hook portion 711, prevent the holding piece 710 from disengaging from the holding portion 611 of the connector 610 to cause disengagement of the plug unit 700 and the connector 610. When the operating rod 400 rotates, the fifth sliding rod 355 is driven to move toward the first side 821 since a side of the fifth sliding rod 355 is pivotally connected to the operating rod 400, causing the limiting portion 390 to move toward the first side 821. In the embodiment shown in FIG. 21B, when the operating rod 400 rotates to a position where the limiting portion 390 is located above the side of the holding piece 710 without the hook portion 711, the limiting portion 390 abuts the side of the holding piece 710 without the hook portion 711, causing the holding piece 710 to disengage from the holding portion 611 of the connector 610, allowing disengagement of the plug unit 700 and the connector 610.

The present invention has been illustrated by the above embodiments. However, the above embodiments are merely examples for implementing the present invention. It must be noted that the disclosed embodiments do not limit the scope of the present invention. On the contrary, modifications and equivalent arrangements that are within the spirit and scope of the appended patent claims are included within the scope of the present invention.

What is claimed is:

1. A connector disassembly module, disposed in a casing, the casing comprising a bottom board and a side board, the side board disposed perpendicular to the bottom board and comprising a first side and a second side on opposite sides, the connector disassembly module comprising:
a first sliding rod disposed on the side board and movable along a first direction;
a first rotating rod pivotally connected to the bottom board and comprising a first driving portion and a second driving portion, wherein the first driving portion and the second driving portion are on opposite sides of the first rotating rod, and the first driving portion is movably connected to the first sliding rod; and
an operating rod comprising a free end and a pivot portion, wherein the pivot portion is pivotally connected to the side board at a position relatively close to the first side and relatively away from the second side, and the operating rod is movably connected to the first sliding rod,
wherein the operating rod is rotatable to move the free end away from the second side, driving the first sliding rod and rotating the first rotating rod to move the second driving portion further away from the first side.

2. The connector disassembly module of claim 1, wherein:
the first sliding rod comprises a first end and a second end positioned at opposite ends respectively close to the first side and the second side, the first sliding rod has a first bump close to the first end and protruding from the first sliding rod in a direction away from the side board, a portion of the first sliding rod close to the second end forms a bent piece bent away from the side board with a gap between the bent piece and the side board, an upper edge of the bent piece forms a recess, a side of the recess close to the first end forms a recess ramp, the bent piece has a second bump protruding from the bent piece toward the side board and located in the gap, the second bump is close to a side of the recess near the second end, the bent piece has a third bump protruding from a lower edge of the bent piece toward the bottom board,
the first driving portion comprises a first guide slot, the third bump is movably disposed in the first guide slot,
the operating rod comprises a guide groove, and the first bump is movably disposed in the guide groove.

3. The connector disassembly module of claim 2, further comprising a limiting module disposed on the side board and movable along the first direction, wherein the limiting module comprises a limiting portion relatively close to the second side and relatively away from the first side.

4. The connector disassembly module of claim 3, further comprising:
a second rotating rod pivotally connected to the side board at a position corresponding to the recess, wherein the second rotating rod comprises a first wing and a second wing positioned on opposite sides of the second rotating rod, the first wing is close to the recess ramp, the second wing comprises a cam extending from a side of the second wing close to the side board toward the bottom board, and the cam is movable to enter the gap,
wherein, when the free end is located relatively close to the second side, the recess ramp abuts an edge of the first wing to keep the first wing away from the bottom board and the second wing close to the bottom board; when the operating rod rotates to move the free end relatively away from the second side, the operating rod drives the first sliding rod to move, then the second bump abuts the cam to keep the second wing away from the bottom board, causing an edge of the second wing to fit into the limiting portion.

5. The connector disassembly module of claim 4, further comprising a first elastic component connected to the limiting module and the side board, providing elasticity to move the limiting module toward the first side, wherein, when the operating rod rotates to move the free end relatively away from the second side, the limiting module is moved toward the first side.

6. The connector disassembly module of claim 5, wherein the limiting module comprises:
a supporting component disposed on the side board and comprising a supporting wall parallel to the bottom board;
a second sliding rod movably disposed on a side of the supporting wall facing the bottom board, wherein a side of the second sliding rod abuts the operating rod; and
a third sliding rod movably disposed on a side of the supporting wall facing the bottom board, wherein the third sliding rod abuts the other side of the second sliding rod relative to the operating rod, the limiting portion is a hook portion extending from an end of the third sliding rod close to the second sliding rod toward the bottom board, and the first elastic component is connected to the third sliding rod and the supporting wall.

7. The connector disassembly module of claim 5, wherein the limiting module comprises:
a supporting component disposed on the side board and comprising a supporting wall parallel to the bottom board; and
a fourth sliding rod movably disposed on a side of the supporting wall facing the bottom board, wherein a side of the fourth sliding rod abuts the operating rod, the limiting portion is a hook portion extending from an end of the fourth sliding rod away from the first side toward the bottom board, and the first elastic component is connected to the fourth sliding rod and the supporting wall.

8. The connector disassembly module of claim 6, wherein the limiting module further comprises an elastic piece disposed on a side of the supporting wall facing the bottom board, and the elastic piece is facing the first wing,
when the elastic piece abuts the first wing, the elastic piece applies force to the first wing, bringing the first wing close to the bottom board and the second wing away from the bottom board.

9. The connector disassembly module of claim 1, wherein the connector disassembly module further comprises a stopping bump disposed on the side board, the limiting module is movable toward the first side until abutting the stopping bump.

10. The connector disassembly module of claim 1, wherein:
the first sliding rod comprises a first end and a second end at opposite ends respectively close to the first side and the second side, the first sliding rod has a first bump close to the first end and protruding from the first sliding rod in a direction away from the side board, an upper edge of a portion of the first sliding rod close to the first end forms a recess, a side of the recess close to the first end forms a recess ramp, the first sliding rod has a third bump close to the second end and protruding from a lower edge of the first sliding rod toward the bottom board,
the first driving portion comprises a first guide slot, the third bump is movably disposed in the first guide slot,
the operating rod comprises a guide groove, and the first bump is movably disposed in the guide groove.

11. The connector disassembly module of claim 10, further comprising a limiting module disposed on the side board and movable along the first direction, wherein the limiting module comprises:
a supporting component disposed on the side board and comprising a supporting wall parallel to the bottom board; and
a fifth sliding rod movably disposed on a side of the supporting wall facing the bottom board, wherein a side of the fifth sliding rod is pivotally connected to the operating rod, another side of the fifth sliding rod comprises an elastic portion bent toward the bottom board, and a hook portion extends from an end of the elastic portion away from the first side toward the bottom board.

12. The connector disassembly module of claim 1, wherein the side board further comprises a positioning bump, and the operating rod comprises:
an operating rod body pivotally connected to the side board; and
a positioning component movably disposed on a side of the operating rod body facing the side board, wherein the positioning component is partially exposed relative to the operating rod body, an end of the positioning component comprises a positioning groove, and the positioning groove is engageable with the positioning bump.

13. The connector disassembly module of claim 1, further comprising a second elastic component connected to the first sliding rod and the side board, providing elastic force to move the first sliding rod toward the second side.

14. A server, comprising:
a casing comprising a bottom board and a side board, wherein the side board is disposed perpendicular to the bottom board and comprises a first side and a second side opposite to each other;
a plug unit disposed on the bottom board and coupled to a cable;
a module disposed on the bottom board and close to the plug unit;
a first sliding rod disposed on the side board and movable along a first direction;
a first rotating rod pivotally connected to the bottom board and comprising a first driving portion and a second driving portion, wherein the first driving portion and the second driving portion are positioned on opposite sides of the first rotating rod, and the first driving portion and the second driving portion is respectively movably connected to the first sliding rod and the module; and
an operating rod comprising a free end and a pivot portion, wherein the pivot portion is pivotally connected to the side board at a position relatively close to the first side and relatively away from the second side, and the operating rod is movably connected to the first sliding rod,
wherein the operating rod is rotatable to move the free end away from the second side, driving the first sliding rod and rotating the first rotating rod to move the second driving portion further away from the plug unit.

15. The server of claim 14, wherein:
the first sliding rod comprises a first end and a second end positioned at opposite ends respectively close to the first side and the second side, the first sliding rod has a first bump close to the first end and protruding from the first sliding rod in a direction away from the side board, a portion of the first sliding rod close to the second end forms a bent piece bent away from the side board with a gap between the bent piece and the side board, an upper edge of the bent piece forms a recess, a side of the recess close to the first end forms a recess ramp, the bent piece has a second bump protruding from the bent piece toward the side board and located in the gap, the second bump is close to a side of the recess near the second end, the bent piece has a third bump protruding from a lower edge of the bent piece toward the bottom board,
the first driving portion comprises a first guide slot, and the third bump is movably disposed in the first guide slot,
the operating rod comprises a guide groove, and the first bump is movably disposed in the guide groove.

16. The server of claim 14, further comprising a limiting module disposed on the side board and movable along the first direction, wherein the limiting module comprises a limiting portion relatively close to the second side and relatively away from the first side.

17. The server of claim 16, further comprising:
a second rotating rod pivotally connected to the side board corresponding to the recess, wherein the second rotating rod comprises a first wing and a second wing positioned on opposite sides of the second rotating rod, the first wing is close to the recess ramp, the second wing comprises a cam extending from a side of the second wing close to the side board toward the bottom board, and the cam is movable to enter the gap,
wherein, when the free end is located relatively close to the second side, the recess ramp abuts an edge of the first wing to keep the first wing away from the bottom board and the second wing close to the bottom board; when the operating rod rotates to move the free end relatively away from the second side, the operating rod drives the first sliding rod to move, the second bump abuts the cam to keep the second wing away from the bottom board, causing an edge of the second wing to fit into the limiting portion.

18. The server of claim 16, wherein the limiting module comprises:
a supporting component disposed on the side board and comprising a supporting wall parallel to the bottom board;
a second sliding rod movably disposed on a side of the supporting wall facing the bottom board, wherein a side of the second sliding rod abuts the operating rod; and
a third sliding rod movably disposed on a side of the supporting wall facing the bottom board, wherein the third sliding rod abuts the other side of the second sliding rod relative to the operating rod, the limiting portion is a hook portion extending from an end of the third sliding rod close to the second sliding rod toward the bottom board, and a first elastic component is connected to the third sliding rod and the supporting wall, providing elastic force to move the third sliding rod toward the first side.

19. The server of claim 16, wherein the limiting module comprises:
a supporting component disposed on the side board and comprising a supporting wall parallel to the bottom board; and
a fourth sliding rod movably disposed on a side of the supporting wall facing the bottom board, wherein a side of the fourth sliding rod abuts the operating rod, the limiting portion is a hook portion extending from an end of the fourth sliding rod away from the first side toward the bottom board, and a first elastic component is connected to the fourth sliding rod and the supporting wall, providing elastic force to move the fourth sliding rod toward the first side.

20. The server of claim 16, wherein:
the first sliding rod comprises a first end and a second end at opposite ends respectively close to the first side and the second side, the first sliding rod has a first bump close to the first end and protruding from the first sliding rod in a direction away from the side board, an upper edge of a portion of the first sliding rod close to the first end forms a recess, a side of the recess close to the first end forms a recess ramp, the first sliding rod has a third bump close to the second end and protruding from a lower edge of the first sliding rod toward the bottom board,
the first driving portion comprises a first guide slot, the third bump is movably disposed in the first guide slot,
the operating rod comprises a guide groove, and the first bump is movably disposed in the guide groove.
